(19) United States
(12) Patent Application Publication
(10) Pub. No.: US 2010/0148303 A1
(43) Pub. Date: Jun. 17, 2010

(54) SEMICONDUCTOR DEVICE AND METHOD FOR FABRICATING THE SAME

(76) Inventor: Shinji Nishiura, Kyoto (JP)

Correspondence Address: MCDERMOTT WILL & EMERY LLP, 600 13TH STREET, NW, WASHINGTON, DC, 20005-3096, US

(21) Appl. No.: 12/613,237

(22) Filed: Nov. 5, 2009

(30) Foreign Application Priority Data
Dec. 11, 2008 (JP) 2008-315511

(51) Int. Cl. H01L 29/86; H01L 21/02; H01L 21/768

(52) U.S. Cl. 257/531; 438/381; 438/597; 257/E21.022; 257/E21.575; 257/E29.325

(57) ABSTRACT

A semiconductor device includes: a semiconductor substrate; an interlayer insulating film formed on the semiconductor substrate; a first inductor interconnect layer having a spiral pattern, formed to be embedded in a top portion of the interlayer insulating film; a barrier insulating film formed to cover the interlayer insulating film and the first inductor interconnect layer, the barrier insulating film having at least one connecting groove running along the first inductor interconnect layer; and a second inductor interconnect layer formed on the barrier insulating film to run along the first inductor interconnect layer and fill the connecting groove to be electrically connected with the first inductor interconnect layer. The second inductor interconnect layer has at least one concave groove formed on the top to run along the length thereof.

### CROSS-REFERENCE TO RELATED APPLICATION

This application claims priority to Japanese Patent Application No. 2008-315511 filed on Dec. 11, 2008, the disclosure of which including the specification, the drawings, and the claims is hereby incorporated by reference in its entirety.

### BACKGROUND

In recent years, monolithic inductor elements fabricated by a semiconductor fabrication process have been used in high-frequency analog integrated circuits, in particular, in high-frequency resonator circuits such as voltage controlled oscillator (VCO) circuits, in the mobile communication field and the like. Inductor elements are essential elements determining the performance of VCO circuits including the current consumption and noise. Hence, the monolithic inductor elements are required to exhibit high performance (a high Q factor).

FIGS. 7 and 8 are views showing structures in plan and in cross section, respectively, of a conventional monolithic inductor element fabricated by a semiconductor fabrication process.

As shown in FIG. 7, a metal interconnect layer 107 (generally, a topmost layer of a multilayer metal interconnect structure) formed by a semiconductor fabrication process is shaped into a spiral pattern, constituting a coil portion of the inductor element.

The spiral inner end of the metal interconnect layer 107 is electrically connected to a metal interconnect layer 104 formed below the metal interconnect layer 107 via vias 108. The metal interconnect layer 104 crosses the spiral region (region where the spiral pattern is formed) under the metal interconnect layer 107 to be drawn outside the spiral region, and is connected to a circuit terminal (not shown). The spiral outer end of the metal interconnect layer 107 is extended to be drawn outside the spiral region, and is connected to another circuit terminal (not shown).

FIG. 8 is a cross-sectional view taken along line VIII-VIII′ in FIG. 7. As shown in FIG. 8, an insulating film 102 that is to be an insulating isolation layer is formed on a semiconductor substrate 101, and a first interlayer insulating film 103 is formed on the insulating film 102. The metal interconnect layer 104 is formed to be embedded in a top portion of the first interlayer insulating film 103.

A first barrier insulating film 105 is formed to cover the first interlayer insulating film and the metal interconnect layer 104, and a second interlayer insulating film 106 is formed on the first barrier insulating film 105. The metal interconnect layer 107 is formed to be embedded in a top portion of the second interlayer insulating film 106. As mentioned with reference to FIG. 7, the end of the metal interconnect layer 104 is below under the spiral inner end of the metal interconnect layer 107. At this position, the vias 108 are formed through the first barrier insulating film 105 and the second interlayer insulating film 106 for electrically connecting the metal interconnect layer 104 with the metal interconnect layer 107.

Note that in a device, a metal interconnect other than the spiral one constituting the inductor element is also formed in the topmost metal interconnect layer. In FIG. 8, such an interconnect is shown as a metal interconnect layer 110. Another barrier insulating film 109 is formed to cover the metal interconnect layer 107, the metal interconnect layer 110, and the second interlayer insulating film 106.

Japanese Patent Gazette No. 2986081 (Document 1) discloses a coil portion constructed of two metal interconnect layers connected in parallel, unlike the conventional monolithic inductor elements in which the coil portion is constructed of a single metal interconnect layer. According to this disclosure, with this double-layer structure, the interconnect resistance (DC resistance) can be reduced, and hence the Q factor improves. As another background technique, Japanese Laid-Open Patent Publication No. 2003-209183 is also known.

To improve the Q factor of the inductor element, it is essential to reduce the interconnect resistance (DC resistance) of the metal interconnect constituting the inductor element, and further reduce the interconnect resistance (high-frequency resistance) during high-frequency operation and reduce the parasitic capacitance generated between the inductor element and the semiconductor substrate.

In the conventional monolithic inductor element shown in FIGS. 7 and 8, the DC resistance is high.

As for the high-frequency resistance, there is an effect, called the skin effect, that during high-frequency operation of an inductor, the flow of a current flowing into the inductor element tends to concentrate in a surface portion of the metal interconnect layer. For this reason, the high-frequency resistance of the inductor element depends largely on the surface area of the interconnect. Since the conventional monolithic inductor element is small in the surface area of the metal interconnect layer, the high-frequency resistance is high.

In the configuration disclosed in Document 1 in which the spiral inductor element is constructed of the topmost metal interconnect layer and its underlying metal interconnect layer connected in parallel for reducing the interconnect resistance (DC resistance), the distance between the metal interconnect layers and the semiconductor substrate is short. This contributes to increase in parasitic capacitance.

From the reasons described above, the conventional monolithic inductor elements have only attained comparatively low Q factors (e.g., less than 5).

### SUMMARY

In view of the above, described hereinafter will be a semiconductor device including a monolithic inductor element that is small in both DC resistance and high-frequency resistance and can obtain a higher Q factor, and a method for fabricating such a semiconductor device.

The semiconductor device of the present disclosure includes: a semiconductor substrate; an interlayer insulating film formed on the semiconductor substrate; a first inductor interconnect layer having a spiral pattern, formed to be embedded in a top portion of the interlayer insulating film; a barrier insulating film formed to cover the interlayer insulating film and the first inductor interconnect layer, the barrier insulating film having at least one connecting groove extending vertically therethrough and running along the first inductor interconnect layer; and a second inductor interconnect layer formed on the barrier insulating film to run along the first inductor interconnect layer and fill the connecting groove to be electrically connected with the first inductor interconnect layer, wherein the second inductor interconnect layer has at least one concave groove formed on the top to run along the length direction of the second inductor interconnect layer.

According to the semiconductor device described above, it is possible to reduce both the DC resistance and high-frequency resistance of the monolithic inductor element while suppressing increase in parasitic capacitance between the semiconductor device and the semiconductor substrate, as described below in detail.

The inductor of the semiconductor device includes the first inductor interconnect layer and the second inductor interconnect layer, both having a spiral pattern, placed in parallel. Having this structure, the DC resistance is widely reduced compared with the conventional structure.

In addition, the second inductor interconnect layer fills the connecting groove and has a concave groove on the top, resulting in having an uneven shape on both the top and bottom thereof. This can increase the surface area of the inductor, and hence increase the portion of the inductor through which the current flows during high-frequency operation in which the skin effect occurs. Hence, the high-frequency resistance can also be widely reduced.

For the above reasons, the Q factor of the inductor can be improved to as large as 10 or more, for example.

Preferably, the semiconductor device further includes an interconnect layer formed below the first inductor interconnect layer and electrically connected with an inner end of the first inductor interconnect layer via at least one metal via, wherein the interconnect layer is drawn outside the spiral pattern.

With the above configuration, “electrical drawing-out” from the inner end of the inductor can be performed.

The concave groove may be located above the connecting groove. This structure is suitable for a fabrication method to follow.

Preferably, a plurality of connecting grooves and a plurality of concave grooves are provided.

With the above configuration, the surface area of the inductor can be further increased, and this is advantageous in reducing the high-frequency resistance.

Preferably, the thickness of the second inductor interconnect layer is greater than the thickness of the first inductor interconnect layer and smaller than the width of the connecting groove.

With the thickened second inductor interconnect layer, the resistance (especially, the DC resistance) of the inductor can be reduced. This is advantageous in improving the Q factor of the inductor. Also, with the thickness of the second inductor interconnect layer smaller than the width of the connecting groove, the concave groove can be formed easily.

Preferably, the semiconductor device further includes: a topmost interconnect layer formed to be embedded in the top portion of the interlayer insulating film and made of the same material as the first inductor interconnect layer; and a pad electrode formed on the barrier insulating film and made of the same material as the second inductor interconnect layer.

That is, it is recommended to form the first inductor interconnect layer using the layer for formation of the topmost interconnect layer and the second inductor interconnect layer using the layer for formation of the pad electrode. This makes it possible to implement an inductor made of a plurality of layers while keeping the distance between the inductor and the semiconductor substrate from being shortened. These are advantageous in reducing the inductor resistance and the parasitic capacitance.

Preferably, the first inductor interconnect layer includes a Cu film, and the second inductor interconnect layer includes an Al film or an AlCu film.

The above materials are examples for the respective interconnect layers. In particular, these materials are preferred when the topmost interconnect layer and the pad electrode are provided.

The method for fabricating a semiconductor device of the present disclosure includes the steps of: (a) forming an interlayer insulating film on a semiconductor substrate; (b) forming a first inductor interconnect layer having a spiral pattern to be embedded in a top portion of the interlayer insulating film; (c) forming a barrier insulating film covering the interlayer insulating film and the first inductor interconnect layer; (d) forming at least one connecting groove through the barrier insulating film to extend vertically therethrough and run along the first inductor interconnect layer; and (e) forming a second inductor interconnect layer on the barrier insulating film to run along the first inductor interconnect layer and fill the connecting groove to be electrically connected with the first inductor interconnect layer, wherein in the step (e), at least one concave groove is formed on the top of the second inductor interconnect layer to run along the length of the second inductor interconnect layer.

By employing the above method for fabricating a semiconductor device, the semiconductor device described earlier can be fabricated.

Preferably, the step (e) includes the step of depositing a film made of Al or AlCu in the connecting groove and on the barrier insulating film by low-temperature sputtering and then forming the film into a predetermined pattern.

By adopting the low-temperature sputtering, the concave shape generated on the top of the film made of Al or AlCu at a position above the connecting groove is prevented from disappearing due to reflowing. Hence, the concave groove can be easily formed on the top of the second inductor interconnect layer. The low-temperature sputtering is a sputtering method conducted at a temperature (e.g., about 100° C.) lower than a temperature used for normal sputtering that is about 200° C., for example.

Preferably, the low-temperature sputtering is conducted at a temperature between 100° C. and 150° C. inclusive.

By adopting a temperature in the above specific temperature range that is lower than that in normal sputtering, the concave groove can be easily formed.

Preferably, the step (e) includes the step of forming a film made of Al or AlCu in the connecting groove and on the barrier insulating film and then etching away a top portion of the film in a predetermined region to form the concave groove.

By employing the above method, the concave groove can be formed irrespective of the depth and the like of the connecting groove. Therefore, by forming a deeper concave groove, for example, it is possible to further increase the surface area of the inductor element and hence contribute to reduction in high-frequency resistance.

Preferably, in the step (b), a topmost interconnect layer made of the same material as the first inductor interconnect layer is formed to be embedded in a top portion of the interlayer insulating film, and in the step (e), a pad electrode made of the same material as the second inductor interconnect layer is formed on the barrier insulating film.

By employing the above method, the first inductor interconnect layer can be formed simultaneously with the topmost interconnect layer, and the second inductor interconnect layer can be formed simultaneously with the pad electrode. This makes it unnecessary to add a new process step, and hence the number of fabrication process steps and the cost increase can be suppressed.

Preferably, the method further includes the steps of: forming another interlayer insulating film and an interconnect layer embedded in a top portion of the another interlayer insulating film on the semiconductor substrate before the step (a); and forming at least one metal via through the interlayer insulating film for electrically connecting the interconnect layer with the first inductor interconnect layer, wherein the interconnect layer is drawn outside the spiral pattern.

By employing the above method, an interconnect layer for performing “electrical drawing-out” from the inner end of the inductor can be provided.

As described above, according to the semiconductor device and the method for fabricating the same of the present disclosure, it is possible reduce the DC resistance and high-frequency resistance of the inductor and suppress the parasitic capacitance between the inductor and the semiconductor substrate. This permits formation of a monolithic inductor element having a high Q factor, and hence the current consumption of a high-frequency analog circuit can be widely reduced.

### BRIEF DESCRIPTION OF THE DRAWINGS

FIGS. 1A and 1B are plan views of an inductor element of an illustrative semiconductor device in an embodiment of the present disclosure.

FIG. 2 is a cross-sectional view of a main portion of the illustrative semiconductor device in the embodiment of the present disclosure.

FIG. 3 is a cross-sectional view of the inductor element of the illustrative semiconductor device in the embodiment of the present disclosure.

FIGS. 4A and 4B are cross-sectional views of alterations of the inductor element of the illustrative semiconductor device in the embodiment of the present disclosure.

FIGS. 5A and 5B are views illustrating fabrication process steps for the illustrative semiconductor device in the embodiment of the present disclosure.

FIGS. 6A and 6B are views illustrating fabrication process steps for the illustrative semiconductor device in the embodiment of the present disclosure following FIG. 5B.

FIG. 7 is a plan view of an inductor element in a conventional semiconductor device.

FIG. 8 is a cross-sectional view of the conventional semiconductor device.

### DETAILED DESCRIPTION

Embodiments of the present disclosure will be described with reference to the accompanying drawings. It should be noted that the sizes, the shapes, the materials, and the like specified hereinbelow are only for the purpose of illustration, and can be changed as appropriate within the range not departing from the gist of the disclosed technique.

### Embodiment 1

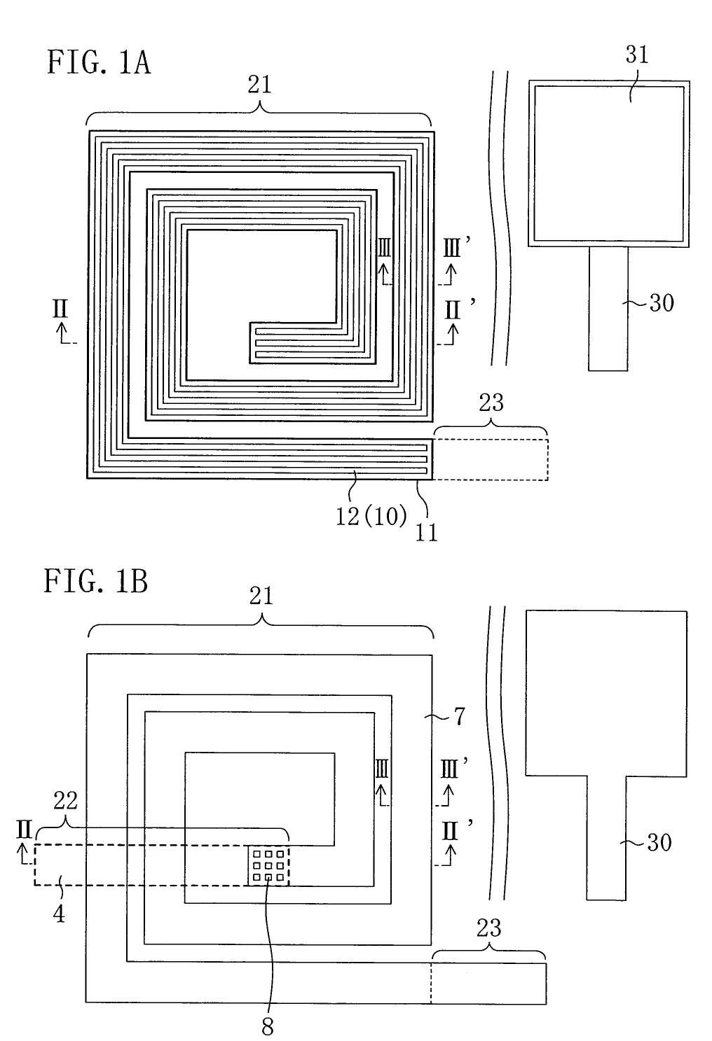

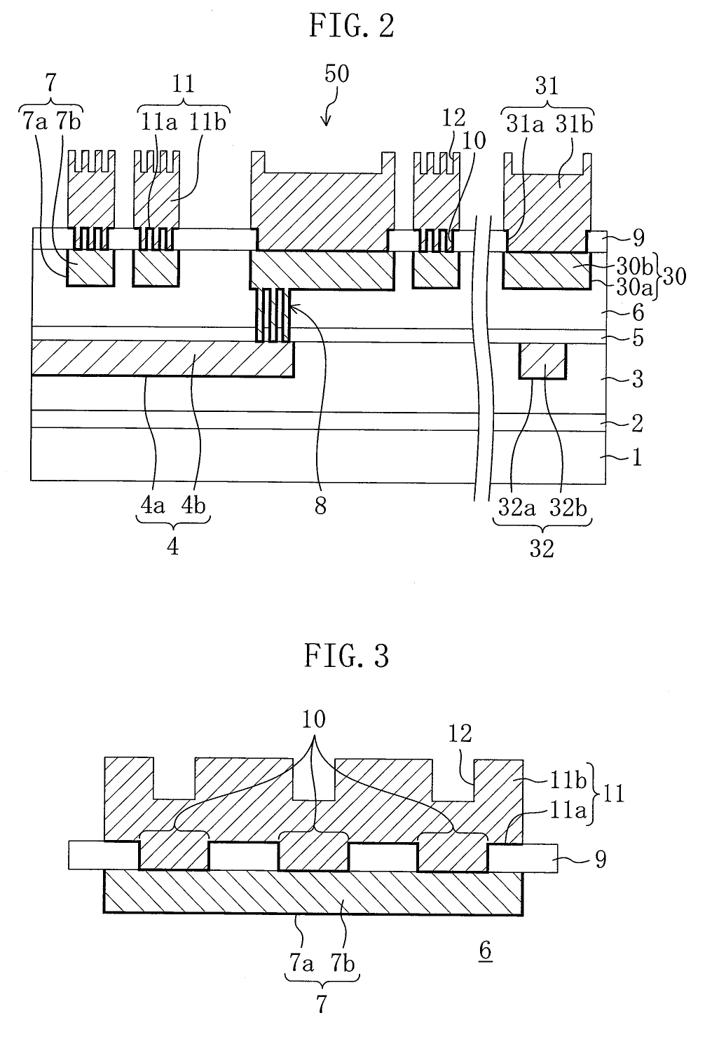

FIGS. 1A and 1B are schematic plan views of a monolithic inductor element of an illustrative semiconductor device 50 in this embodiment. FIG. 2 is a schematic cross-sectional view of the semiconductor device 50, taken along line II-II′ in FIGS. 1A and 1B. FIG. 3 is an enlarged cross-sectional view of the inductor, taken along line in FIGS. 1A and 1B. Both FIGS. 2 and 3 depict the cross section exaggerating the thicknesses of the layers in different degrees of emphasis. It can be said that FIG. 3 is closer to the actual shape (in aspect ratio, etc.) than FIG. 2, but still does not necessarily reflect it correctly.

As shown in FIG. 2, the semiconductor device 50 is formed using a semiconductor substrate 1. An insulating film 2 that is to be an insulating isolation layer is formed on the semiconductor substrate 1, and a first interlayer insulating film 3 is formed on the insulating film 2. The insulating film 2 is made of a SiO₂ film, for example, and the first interlayer insulating film 3 is made of a SiO₂ film, for example.

A metal interconnect layer 4 that is to be a lead for the inductor element is formed in the top portion of the first interlayer insulating film 3. The metal interconnect layer 4 has a structure including a barrier metal film 4a formed on the sides and bottom of a groove on the first interlayer insulating film 3 and a Cu film 4b with which the groove coated with the barrier metal film 4a is filled.

A first barrier insulating film 5, which is made of a SiN film, for example, for preventing Cu diffusion, is formed to cover the first interlayer insulating film 3 and the metal interconnect layer 4. A second interlayer insulating film 6 made of a SiO₂ film is formed on the first barrier insulating film 5.

A first inductor interconnect layer 7 as a component of the coil portion of the inductor element is formed to be embedded in the top portion of the second interlayer insulating film 6. The first inductor interconnect layer 7 has a structure including a barrier metal film 7a and a Cu film 7b. Metal vias 8 are formed through the first barrier insulating film 5 and the second interlayer insulating film 6 for connecting the metal interconnect layer 4 with the first inductor interconnect layer 7.

A second barrier insulating film 9 made of a SiN film, for example, is formed to cover the second interlayer insulating film 6 and the first inductor interconnect layer 7. The second barrier insulating film 9 has connecting grooves 10 extending therethrough vertically (in the thickness direction) that run along the length of the first inductor interconnect layer 7.

A second inductor interconnect layer 11 is formed on the first inductor interconnect layer 7 via the second barrier insulating film 9 to run along the first inductor interconnect layer 7. The second inductor interconnect layer 11 has a structure including a barrier metal film 11a and an AlCu film 11b, and is connected with the first inductor interconnect layer 7 via the connecting grooves 10 that are filled with the second inductor interconnect layer 11.

Concave grooves 12 are formed on the top of the second inductor interconnect layer 11 to run along the length of the second inductor interconnect layer 11.

The second inductor interconnect layer 11 has projections as the portions inside the connecting grooves 10 on the bottom and has the concave grooves 12 on the top. That is, the second inductor interconnect layer 11 has projections and depressions on both the top and bottom thereof, and these projections and depressions run in the direction in which the second inductor interconnect layer 11 runs (length direction). The concave grooves 12 are located above the connecting grooves 10.

As described above, the first inductor interconnect layer 7 and the second inductor interconnect layer 11 are placed in parallel and connected with each other at the portions inside the connecting grooves 10, to constitute the coil portion of the inductor element.

Next, the plan configuration of the semiconductor device 50 including the inductor element will be described with reference to FIGS. 1A and 1B.

FIG. 1A shows the second inductor interconnect layer 11 placed on the first inductor interconnect layer 7 via the second barrier insulating film 9.

The spiral double-layer portion of the first inductor interconnect layer 7 and the second inductor interconnect layer 11 constitutes a coil portion 21 of the inductor element. A coil outer end lead portion 23 connected to the outer end of the coil portion 21 is made of only the first inductor interconnect layer 7, and is connected to a terminal (not shown) of an integrated circuit at a position outside the coil portion 21.

The line width of the spiral pattern is about 5 pm to 50 pm, for example, and the spacing between lines is 3 μm or more, for example.

Also shown are the concave grooves 12 formed on the top of the second inductor interconnect layer 11. A plurality of (three in the illustrated example) concave grooves 12 run along the length of the second inductor interconnect layer 11. Under the concave grooves 12, the connecting grooves 10 are formed through the second barrier insulating film 9.

FIG. 1B shows the first inductor interconnect layer 7 and the metal interconnect layer 4 formed under the first inductor interconnect layer 7. The metal interconnect layer 4 constitutes a coil inner end lead portion 22 together with the metal vias 8 for connection with the inner end of the inductor element. The coil inner end lead portion 22 crosses the coil portion 21 under the first inductor interconnect layer 7 to be electrically drawn outside the coil portion 21, and is connected to a terminal (not shown) of the integrated circuit.

The semiconductor device 50 includes, not only the portion constituting the inductor element, but also a topmost interconnect layer 30, which has a structure including a barrier metal film 30a and a Cu film 30b, like the first inductor interconnect layer 7. Also provided is a pad electrode 31 connected to the topmost interconnect layer 30, which has a structure including a barrier metal film 31a and an AlCu film 31b, like the second inductor interconnect layer 11. Moreover, at the level of the metal interconnect layer 4 as the lead interconnect, another metal interconnect layer 32 constituting the integrated circuit is also provided, which has a structure including a barrier metal film 32a and a Cu film 32b, like the metal interconnect layer 4. These components are also shown in FIGS. 1A, 1B, and 2.

The structure of the coil portion 21 of the inductor element will be described with reference to FIG. 3. As shown in FIG. 3, the coil portion 21 of the inductor element includes the first inductor interconnect layer 7 and the second inductor interconnect layer 11 formed on the first inductor interconnect layer 7 via the second barrier insulating film 9. The first inductor interconnect layer 7 includes the barrier metal film 7a having a thickness of about 20 nm and the Cu film 7b having a thickness of about 600 nm, for example, and has a sheet resistance of about 40 mΩ/□. The second inductor interconnect layer 11 includes the barrier metal film 11a having a thickness of about 130 nm and the AlCu film 11b having a thickness of about 2.5 μm, for example, and has a sheet resistance of about 10 mΩ/□. The second barrier insulating film 9 is a SiN film, for example, having a thickness of about 500 nm.

The connecting grooves 10, formed through the second barrier insulating film 9 to connect the first inductor interconnect layer 7 with the second inductor interconnect layer 11 in parallel, have a width of about 3 μm and an inter-groove spacing of about 3 μm, for example. The number of connecting grooves 10 is according to the line width of the spiral pattern.

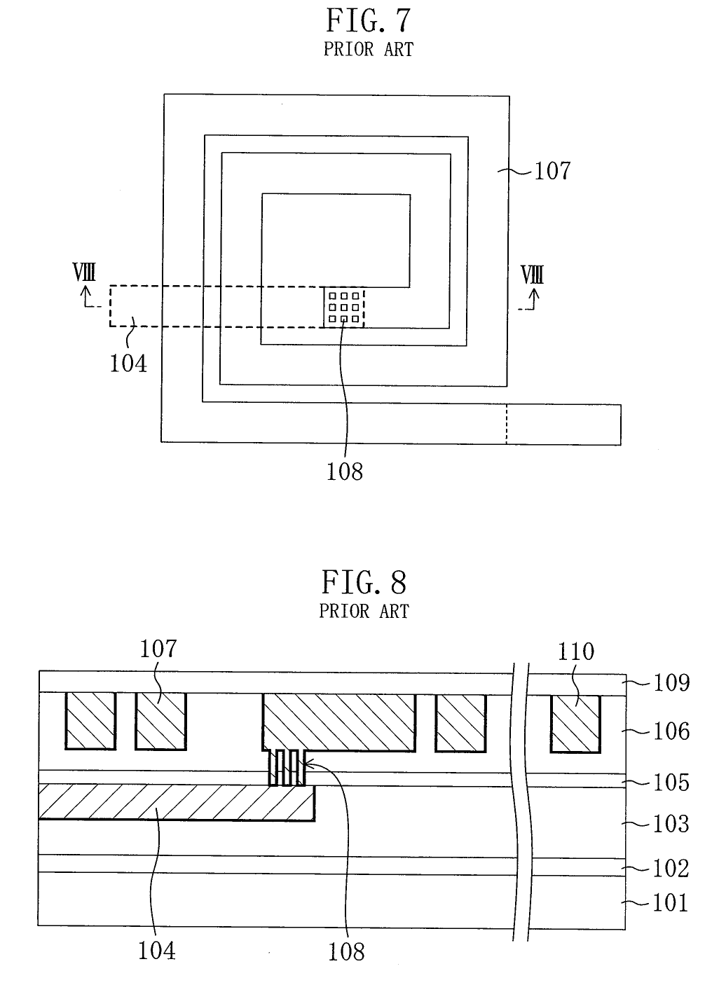

In the inductor element of the semiconductor device 50, having the double-layer structure of the first inductor interconnect layer 7 and the second inductor interconnect layer 11, the sheet resistance of the coil portion 21 is as small as about 8 mΩ/□. Hence, in the semiconductor device 50, the DC resistance of the monolithic inductor element is reduced to about one-fifth of that of the single-layer inductor element shown in FIGS. 7 and 8. The DC resistance is also about one-third even compared with that of the double-layer inductor element disclosed in Document 1. Since the DC resistance can be reduced in this way, the Q factor of the inductor element can be increased.

In the coil portion 21, also, the second inductor interconnect layer 11 has projections (having a step of about 500 nm) as the portions inside the connecting grooves 10 on the bottom and depressions (having a step of about 500 nm) as the concave grooves 12 on the top. With these uneven top and bottom surfaces, the surface area of the coil portion 21 can be increased. For example, in comparison with the case of Document 1, the surface area can be increased by about 10%. In addition, since both the connecting grooves 10 and the concave grooves 12 run along the coil portion 21, the current is allowed to flow along the coil portion 21 in the vicinities of the surfaces of these grooves. For these reasons, the high-frequency resistance can be reduced during high-frequency operation in which the skin effect occurs, and as a result, the Q factor can be improved.

Also, since the first inductor interconnect layer 7 is formed in the same layer as the topmost interconnect layer 30 in the semiconductor device 50, the inductor element can be at the farthest possible position from the semiconductor substrate 1. For example, if six Cu interconnect layers are formed, the distance between the inductor element and the semiconductor substrate will be about 5 μm in the semiconductor device 50. In the case of Document 1 in which two interconnect layers (the topmost sixth layer and the fifth layer) are connected in parallel, the distance will be 4 μm. With this increase in distance, the parasitic capacitance generated between the inductor element and the semiconductor substrate can be reduced, and hence the Q factor can be increased.

As for the second inductor interconnect layer 11 formed in the same layer as the pad electrode 31, the thickness can be set comparatively freely, and this can be used for reducing the resistance of the coil portion 21.

As described above, in the semiconductor device 50, the monolithic inductor element can be widely reduced in DC resistance, high-frequency resistance and parasitic capacitance. As a result, the Q factor, which is conventionally about less than 5 in general, can be improved to as large as 10 or more, for example.

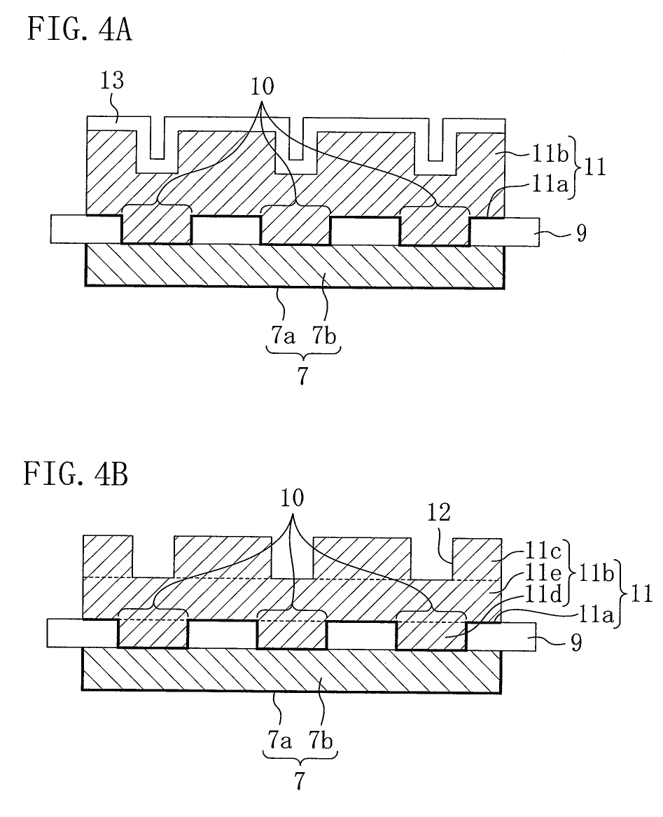

Note that as shown in FIG. 4A, a metal film 13 (a gold film, a copper film, etc.) larger in electric conductivity than the AlCu film 11b may be formed on the AlCu film 11b of the second inductor interconnect layer 11, to further reduce the high-frequency resistance and hence improve the Q factor.

In the above description, the second inductor interconnect layer 11 is formed integrally from the projections as the portions inside the connecting grooves 10 on the bottom through the projections flanking the concave grooves 12 on the top. Alternatively, as shown in FIG. 4B, projections 11c on the top and/or projections 11d on the bottom may be formed separately from a body portion 11e, and these individual portions and the barrier metal film 11a may constitute the second inductor interconnect layer 11.

In the above description, the second inductor interconnect layer 11 is formed over the entire of the first inductor interconnect layer 7 in the coil portion 21. Although this configuration is desired, the configuration is not limited to this. For example, the second inductor interconnect layer 11 may not be formed in a region at and around the outer end or inner end of the coil portion 21.

The connecting grooves 10 and the concave grooves 12 are formed continuously along the entire coil portion 21. Although this configuration is desired, the configuration is not limited to this. The connecting grooves 10 and the concave grooves 12 may be intermittent partly, or may not be formed at all in some regions. In such cases, also, some degree of effect will be obtained.

### Embodiment 2

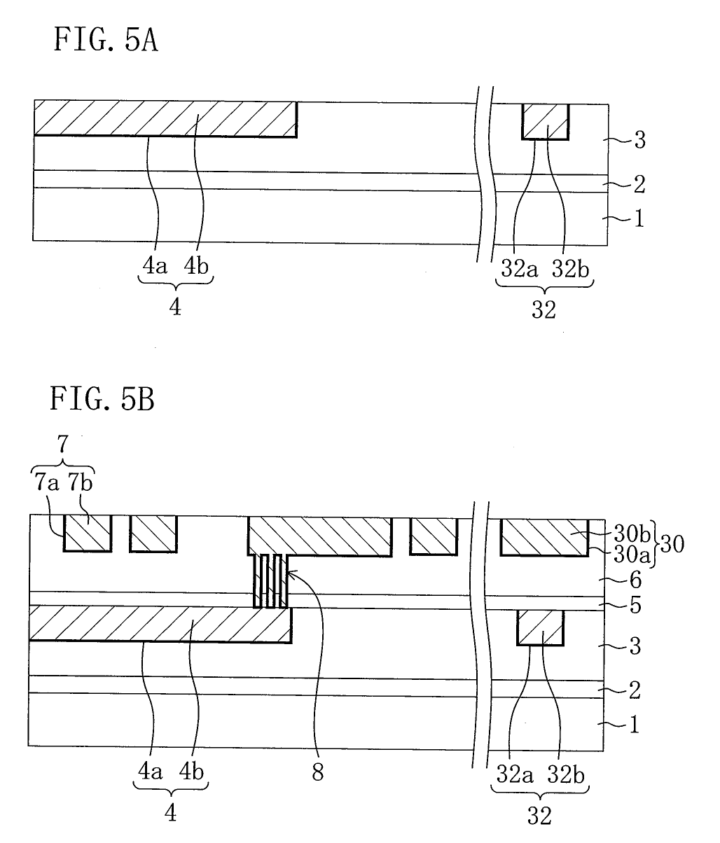

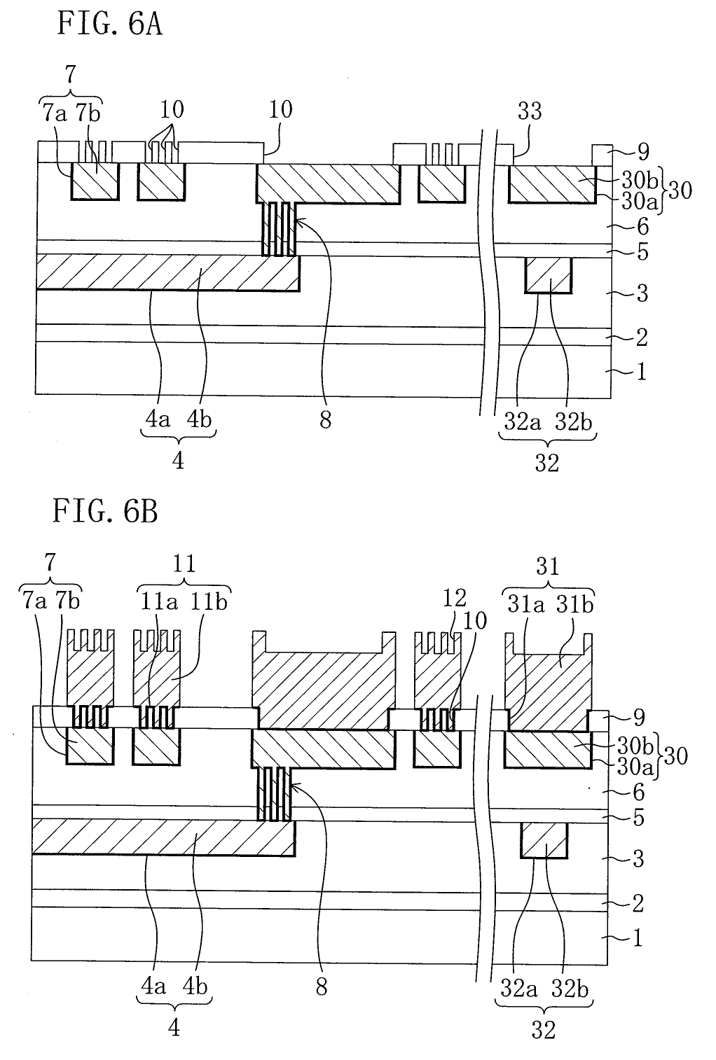

As Embodiment 2, a method for fabricating the illustrative semiconductor device 50 in Embodiment 1 will be described. FIGS. 5A, 5B, 6A, and 6B are schematic cross-sectional views illustrating fabrication process steps for the semiconductor device 50 including the monolithic inductor element.

First, as shown in FIG. 5A, the insulating film 2 that is to be an insulating isolation layer is formed on the semiconductor substrate 1, and the first interlayer insulating film 3 is formed on the insulating film 2.

Thereafter, the metal interconnect layer 4 that is to be the lead interconnect for the inductor element is formed so as to be embedded in the top portion of the first interlayer insulating film 3. For this formation, a lead interconnect groove having the pattern of the metal interconnect layer 4 is formed on the first interlayer insulating film 3. A TaN film having a thickness of about 20 nm is then deposited on the bottom and sides of the lead interconnect groove by sputtering, to form the barrier metal film 4a. The barrier metal film 4a is formed for prevention of Cu diffusion and oxidation.

Subsequently, a Cu film having a thickness of about 100 nm is deposited on the barrier metal film 4a by sputtering, and then a Cu film is deposited over the entire surface of the first interlayer insulating film 3 and over the already-deposited Cu film by field plating. The unnecessary portions of the Cu film and the TaN film protruding from the lead interconnect groove are polished away by chemical mechanical polishing (CMP). In this way, the metal interconnect layer 4 including the barrier metal film 4a and the Cu film 4b is formed so as to fill the lead interconnect groove formed in the top portion of the first interlayer insulating film 3.

Note that the other metal interconnect layer 32 constituting the integrated circuit is also formed in the same process step as the metal interconnect layer 4 that is to be the lead interconnect.

Next, as shown in FIG. 5B, the first barrier insulating film 5 is formed to cover the first interlayer insulating film 3 including the metal interconnect layer 4 and the metal interconnect layer 32. For this formation, a SiN film having a thickness of about 200 nm is deposited by chemical vapor deposition (CVD). The first barrier insulating film 5 is formed for prevention of Cu diffusion and oxidation.

Subsequently, a SiO₂ film is formed on the first barrier insulating film 5 by CVD and then flattened by CMP to form the second interlayer insulating film 6.

A coil interconnect groove having the spiral pattern of the coil portion 21 of the inductor element is formed on the top of the second interlayer insulating film 6. Via openings for formation of the metal vias 8 are then formed in a predetermined region in the coil interconnect groove. The via openings should extend through the second interlayer insulating film 6 and the first barrier insulating film 5 to reach the metal interconnect layer 4.

Thereafter, a TaN film having a thickness of about 20 nm is deposited to cover the bottoms and sides of the coil interconnect groove and the via openings by sputtering to form the barrier metal film 7a. The barrier metal film 7a is formed for prevention of Cu diffusion and oxidation. Subsequently, a Cu film having a thickness of about 100 nm is deposited on the barrier metal film 7a by sputtering, and then a Cu film is deposited over the entire surface of the second interlayer insulating film 6 and over the already-deposited Cu film by field plating. The unnecessary portions of the Cu film and the TaN film protruding from the coil interconnect groove are polished away by CMP. In this way, the first inductor interconnect layer 7 and the metal vias 8 both made of the barrier metal film 7a and the Cu film 7b are formed by filling the coil interconnect groove formed in the top portion of the second interlayer insulating film 6 and the via openings.

Note that the topmost interconnect layer 30 (the portion other than the first inductor interconnect layer 7) of the multilayer interconnect structure constituting the integrated circuit is also formed in the same process step as the first inductor interconnect layer 7 constituting the inductor element.

Next, as shown in FIG. 6A, a SiN film as the second barrier insulating film is formed on the entire surface of the second interlayer insulating film 6 including the first inductor interconnect layer 7 and the topmost interconnect layer 30. The SiN film is formed to a thickness of about 500 nm by CVD for prevention of Cu diffusion and oxidation.

Subsequently, the connecting grooves 10 and an opening 33 are formed through the second barrier insulating film 9 by photolithography and reactive ion etching (RIE) to reach the Cu film 7b of the first inductor interconnect layer 7 and the Cu film 30b of the topmost interconnect layer 30, respectively.

Next, as shown in FIG. 6B, a Ti film having a thickness of about 30 nm is formed on the second barrier insulating film 9 and in the connecting groove 10 by sputtering, and then a TiN film having a thickness of about 100 nm is deposited on the Ti film, to form the barrier metal film 11a. Thereafter, an AlCu film 11b having a thickness of about 2.5 μm is deposited on the barrier metal film 11a by sputtering. The barrier metal film 11a is formed for prevention of Cu diffusion and oxidation.

The sputtering for formation of the AlCu film 11b is made under the condition of a comparatively low temperature such as about 100° C., for example. With this low-temperature sputtering, the connecting grooves 10 can be filled with AlCu, and also the concave shape of the connecting grooves 10 in the second barrier insulating film 9 is transferred to the top of the AlCu film 11b, forming the concave grooves 12 on the top of the AlCu film 11b. This is because reflowing of AlCu is suppressed under the low-temperature condition.

As described above, the second inductor interconnect layer 11 has the portions inside the connecting grooves 10 on the bottom and has the concave grooves 12 on the top. With these uneven top and bottom surfaces, the surface area of the inductor element increases, and hence the high-frequency resistance is reduced.

Note that sputtering is normally conducted under the condition of about 200° C., for example. Although the temperature in the low-temperature sputtering is specified above as about 100° C. as an example, it can be any temperature within the temperature range at which sputtering is permitted and reflowing can be suppressed. For example, the temperature range may be about 100° C. to 150° C.

The barrier metal film 11a and the AlCu film 11b are then formed into a spiral pattern running along the first inductor interconnect layer 7 by lithography and RIE, to form the second inductor interconnect layer 11. In this way, the inductor element is formed, in which the second inductor interconnect layer 11 is placed on the first inductor interconnect layer 7 and connected therewith in parallel via the portions inside the connecting grooves 10.

Note that the pad electrode 31 connected with the topmost interconnect layer 30 via the opening 33 is also formed on a predetermined portion of the topmost interconnect layer 30 simultaneously with the formation of the second inductor interconnect layer 11.

In the manner described above, the semiconductor device 50 including the monolithic inductor element having a multilayer structure of two metal layers (inductor interconnect layers) connected in parallel is formed.

The upper layer (second inductor interconnect layer 11) out of the two metal layers constituting the inductor, which is formed using the layer for the pad electrode 31, can be thickened without being restricted by rules on routing formation of the integrated circuit. This can greatly reduce the DC resistance of the inductor. In addition, since the second inductor interconnect layer 11 is formed simultaneously with the pad electrode 31, it can be formed without increasing the fabrication process steps.

The lower layer (first inductor interconnect layer 7) out of the two metal layers constituting the inductor is formed using the same layer as the topmost interconnect layer 30 that is the interconnect layer farthest from the semiconductor substrate 1. Hence, with the increased distance between the inductor element and the semiconductor substrate 1, the parasitic capacitance can be reduced. In addition, the first inductor interconnect layer 7 can be formed without increasing the fabrication process steps compared with the conventional case.

Since the AlCu film 11b is formed by low-temperature sputtering, the concave shape of the connecting grooves 10 can be transferred to the top of the film as the concave grooves 12. This eliminates the necessity of a new process step for forming an uneven shape on the top of the second inductor interconnect layer 11.

As described above, the semiconductor device 50 having the effects described in Embodiment 1 can be fabricated without increase in fabrication process steps.

Another method may be employed for formation of the second inductor interconnect layer 11. For example, the following method may be considered.

After the formation of the barrier metal film 11a in FIG. 6B, the AlCu film 11b is formed by normal sputtering. In this formation, the top surface of the AlCu film 11b may be flat. Thereafter, the top portion of the AlCu film 11b is etched by photolithography and RIE to form the concave grooves 12 of a predetermined pattern. The AlCu film 11b is then formed into the shape running along the spiral pattern of the first inductor interconnect layer 7 by photolithography and RIE, again, to form the second inductor interconnect layer 11 together with the barrier metal film 11a.

The above method may increase the number of fabrication process steps, but can increase the degree of freedom on the shape of the concave grooves 12. In other words, the concave grooves 12 can be formed irrespective of the depth, width, quantity of the connecting grooves 10. In particular, concave grooves 12 deeper than the connecting grooves 10 can be formed. This permits further increase in the surface area of the second inductor interconnect layer 11, and hence contributes to reduction in high-frequency resistance.

A process step of forming a metal film (a gold film, a copper film, etc.) larger in electric conductivity than the AlCu film 11b on the AlCu film 11b of the second inductor interconnect layer 11 (forming the structure shown in FIG. 4A) may further be provided.

The semiconductor device and the method for fabricating the same of the present disclosure described above permits implementation of a semiconductor device including a monolithic inductor element high in Q factor (e.g., 10 or more), and are useful in enhancing the performance of a high-frequency analog integrated circuit.

What is claimed is:

1. A semiconductor device, comprising:
a semiconductor substrate;
an interlayer insulating film formed on the semiconductor substrate;
a first inductor interconnect layer having a spiral pattern, formed to be embedded in a top portion of the interlayer insulating film;
a barrier insulating film formed to cover the interlayer insulating film and the first inductor interconnect layer, the barrier insulating film having at least one connecting groove extending vertically therethrough and running along the first inductor interconnect layer; and
a second inductor interconnect layer formed on the barrier insulating film to run along the first inductor interconnect layer and fill the connecting groove to be electrically connected with the first inductor interconnect layer, wherein
the second inductor interconnect layer has at least one concave groove formed on the top to run along a length direction of the second inductor interconnect layer.

2. The device of claim 1, further comprising:
an interconnect layer formed below the first inductor interconnect layer and electrically connected with an inner end of the first inductor interconnect layer via at least one metal via,
wherein
the interconnect layer is drawn outside the spiral pattern.

3. The device of claim 1, wherein
the concave groove is located above the connecting groove.

4. The device of claim 1, wherein
a plurality of connecting grooves and a plurality of concave grooves are provided.

5. The device of claim 1, wherein
the thickness of the second inductor interconnect layer is greater than the thickness of the first inductor interconnect layer and smaller than the width of the connecting groove.

6. The device of claim 1, further comprising:
a topmost interconnect layer formed to be embedded in the top portion of the interlayer insulating film and made of the same material as the first inductor interconnect layer; and
a pad electrode formed on the barrier insulating film and made of the same material as the second inductor interconnect layer.

7. The device of claim 1, wherein
the first inductor interconnect layer includes a Cu film, and
the second inductor interconnect layer includes an Al film or an AlCu film.

8. A method for fabricating a semiconductor device, comprising the steps of:
(a) forming an interlayer insulating film on a semiconductor substrate;
(b) forming a first inductor interconnect layer having a spiral pattern to be embedded in a top portion of the interlayer insulating film;
(c) forming a barrier insulating film covering the interlayer insulating film and the first inductor interconnect layer;
(d) forming at least one connecting groove through the barrier insulating film to extend vertically therethrough and run along the first inductor interconnect layer; and
(e) forming a second inductor interconnect layer on the barrier insulating film to run along the first inductor interconnect layer and fill the connecting groove to be electrically connected with the first inductor interconnect layer,
wherein
in the step (e), at least one concave groove is formed on the top of the second inductor interconnect layer to run along the length of the second inductor interconnect layer.

9. The method of claim 8, wherein
the step (e) includes the step of depositing a film made of Al or AlCu in the connecting groove and on the barrier insulating film by low-temperature sputtering and then forming the film into a predetermined pattern.

10. The method of claim 9, wherein
the low-temperature sputtering is conducted at a temperature between 100° C. and 150° C. inclusive.

11. The method of claim 8, wherein
the step (e) includes the step of forming a film made of Al or AlCu in the connecting groove and on the barrier insulating film and then etching away a top portion of the film in a predetermined region to form the concave groove.

12. The method of claim 8, wherein
in the step (b), a topmost interconnect layer made of the same material as the first inductor interconnect layer is formed to be embedded in a top portion of the interlayer insulating film, and
in the step (e), a pad electrode made of the same material as the second inductor interconnect layer is formed on the barrier insulating film.

13. The method of claim 8, further comprising the steps of:
forming another interlayer insulating film and an interconnect layer embedded in a top portion of the another interlayer insulating film on the semiconductor substrate before the step (a); and
forming at least one metal via through the interlayer insulating film for electrically connecting the interconnect layer with the first inductor interconnect layer, wherein
the interconnect layer is drawn outside the spiral pattern.
